(19) United States
(12) Patent Application Publication
(10) Pub. No.: US 2010/0065255 A1
(43) Pub. Date: Mar. 18, 2010

(54) Vapor Chamber

(75) Inventors: Juei-Khai Liu, Taipei (TW); Yu-Wei Chang, Taipei (TW); Chao-Tsai Chung, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: PEGATRON CORPORATION, Taipei (TW)

(21) Appl. No.: 12/559,646

(22) Filed: Sep. 15, 2009

(30) Foreign Application Priority Data
Sep. 18, 2008 (TW) 97135890

(51) Int. Cl. F28D 15/04; H05K 7/20

(52) U.S. Cl. 165/104.26; 165/104.33

(57) ABSTRACT

A vapor chamber includes a chamber, a working fluid, a lower wick structure, and a plurality of supporting elements. The chamber includes an upper cover and a bottom plate and contains the working fluid. The lower wick structure is located at the bottom plate. The supporting elements are disposed in the chamber and connect the upper cover and the bottom plate to support the upper cover. Each of the supporting elements and the upper cover form a first inclined angle. The working fluid in the vapor phase flows from the upper cover back to the bottom plate through the supporting elements after condensed.

### CROSS-REFERENCES TO RELATED APPLICATIONS

This non-provisional application claims priority under 35 U.S.C. §119(a) on Patent Application No. TW 97135890 filed in Taiwan, R.O.C. on Sep. 18, 2008, the entire contents of which are hereby incorporated by reference.

### BACKGROUND OF THE INVENTION

1. Field of the Invention

The invention relates to a vapor chamber and, more particularly, to a vapor chamber with an enhanced heat transfer capability.

2. Description of the Related Art

With development of information and science, a semiconductor power transistor (such as a CPU, a GPU, and a high power LED) becomes smaller and smaller, heat generated by the power transistor becomes higher and higher, and power density, i.e. heat flux density, becomes greater and greater. To keep operation of an element at an allowable temperature, the electronic element is combined with different types of heat sinks for dissipating heat. A vapor chamber has high thermo-conductivity, a high heat transfer capability, and a simple structure, and it is light and power-saving. The vapor chamber is suitable for heat dissipation of the electronic element, and the application of the vapor chamber becomes more and more popular.

In FIG. 1 and FIG. 2, a conventional vapor chamber A1 mainly includes a casing A10, a wick structure A20, a plurality of supporting elements A30, and a working fluid A40. The wick structure A20 covers inner walls of the casing A10. The supporting elements A30 support the casing A10. The casing A10 contains the working fluid A40. The supporting element A30 is generally a solid cylinder, a cylinder made of a porous material, a rectangular pillar, or other structures, such as the structures in a U.S. Pat. No. 3,613,778, a U.S. Pat. No. 5,769,154, a U.S. Pat. No. 6,167,948, a U.S. Pat. No. 6,227,287, a U.S. Pat. No. 6,269,866, a U.S. Pat. No. 6,302,192, a U.S. Pat. No. 6,397,935, or a U.S. Pat. No. 7,264,041 and so on.

When the vapor chamber A1 is used, after the working fluid A40 in the upper space of the casing A10 is condensed, the working fluid A40 flows to the wick structure A20 at the lower space of the casing A10 by the guiding of the wick structure A20 and the supporting elements A30, and then the working fluid A40 flows back to a heating area at a central space by the guiding of the capillary force provided by the wick structure A20 at the lower space of the casing A10. To increase a heat dissipation area and improve heat dissipation efficiency, a ratio between a cooling base area of the vapor chamber A1 (that is, the product area of length and width of the vapor chamber) and a partial heating area (that is, a heating area of a power transistor) greatly increases, thus to lengthen a circular route of the working fluid A40. However, the longer circular route and smaller capillary permeability may generate greater flowing resistance, further to reduce the heat transfer capability of the vapor chamber A1. In addition, a mechanical strength of the vapor chamber A1 is weak, and the vapor chamber A1 fails to bear an internal water vapor pressure when the temperature reaches 150° C. (about 4.7 atm). Therefore, it is rather disadvantage to assemble the heat dissipation module by soldering.

### BRIEF SUMMARY OF THE INVENTION

This invention provides a vapor chamber for contacting a heat source. The embodiment of the vapor chamber includes a chamber, a working fluid, a lower wick structure, and a plurality of supporting elements. The chamber includes an upper cover and a bottom plate for contacting the heat source, and the lower wick structure is located at the bottom plate. The chamber contains the working fluid which is converted into vapor after absorbing heat of the heat source. The supporting elements are disposed in the chamber and connect the upper cover and the bottom plate to support the upper cover. Each of the supporting elements and the upper cover form a first inclined angle, and the inclined angle is defined as a non-vertical angle. The working fluid in the vapor phase flows from the upper cover back to the bottom plate through the supporting elements after condensed.

In one embodiment, a passage may be formed between the adjacent supporting elements, and a ratio between a capillary radius of the first inclined angle and a hydraulic radius of the passage may be greater than or equal to one.

According to the invention, the condensed working fluid flows from the upper cover back to the bottom plate through the supporting elements via the additional capillary force provide by an acute angle area of the first inclined angle, further to improve permeability of the wick structure, to reduce reflowing resistance of the working fluid, and to increase a mass flow rate of the working fluid, thereby improving the heat transfer capability of the vapor chamber. In addition, according to the invention, when the upper cover and the bottom plate are soldered under a high temperature (having a soldering material or without a soldering material), contacting surfaces between the supporting elements and the upper cover and the bottom plate (or the upper and lower wick structure) are tightly connected via molecule expansion soldering, thereby providing a better mechanical strength.

These and other features, aspects, and advantages of the present invention will become better understood with regard to the following description, appended claims, and accompanying drawings.

### BRIEF DESCRIPTION OF THE DRAWINGS

FIG. 1 is a plane schematic diagram showing a conventional vapor chamber;

FIG. 2 is a sectional schematic diagram showing the vapor chamber along a line A-A′ in FIG. 1;

FIG. 3 is a plane schematic diagram showing a vapor chamber according to a first embodiment of the invention;

FIG. 4 is a sectional schematic diagram showing the vapor chamber along a line B-B′ in FIG. 3;

FIG. 5 is a sectional schematic diagram showing the vapor chamber along a line C-C′ in FIG. 3;

FIG. 6 is a first schematic diagram showing supporting elements according to the first embodiment of the invention;

FIG. 7 is a second schematic diagram showing supporting elements according to the first embodiment of the invention;

FIG. 8 is a sectional schematic diagram showing a vapor chamber according to a second embodiment of the invention;

FIG. 9 is a first schematic diagram showing a supporting element according to the second embodiment of the invention;

FIG. 10 is a second schematic diagram showing a supporting element according to the second embodiment of the invention;

FIG. 11 is a third schematic diagram showing a supporting element according to the second embodiment of the invention; and

FIG. 12 is a fourth schematic diagram showing a supporting element according to the second embodiment of the invention.

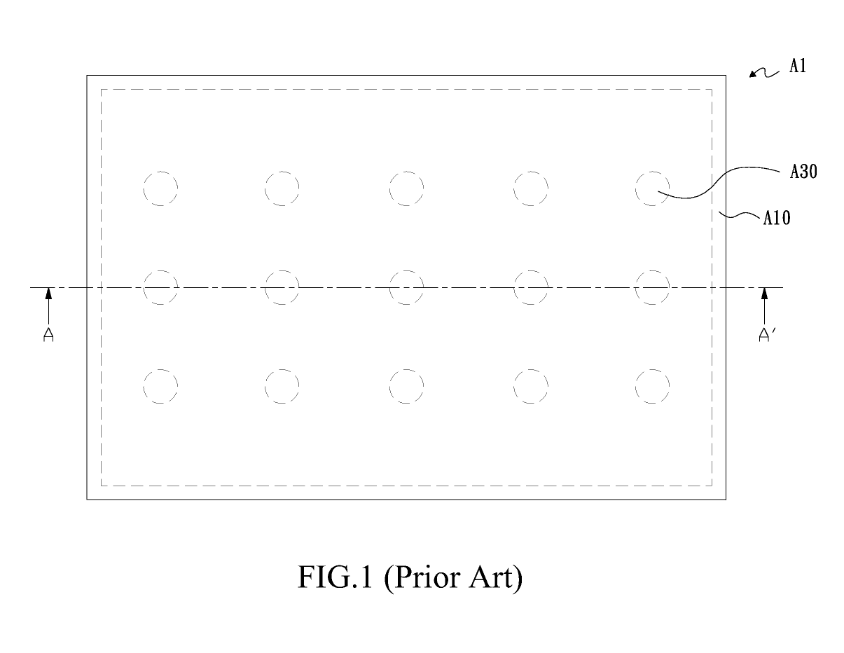

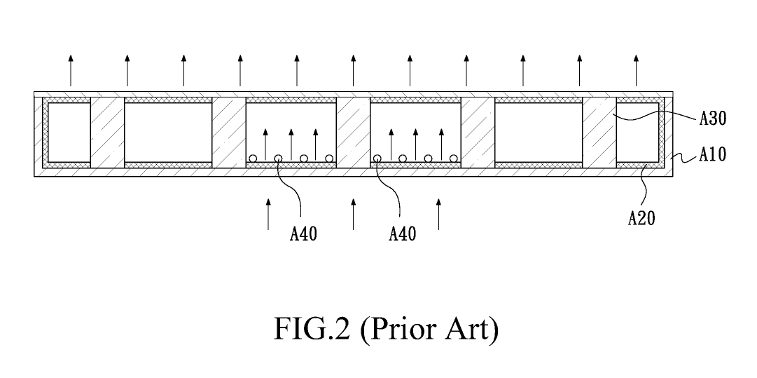

### DETAILED DESCRIPTION OF THE INVENTION

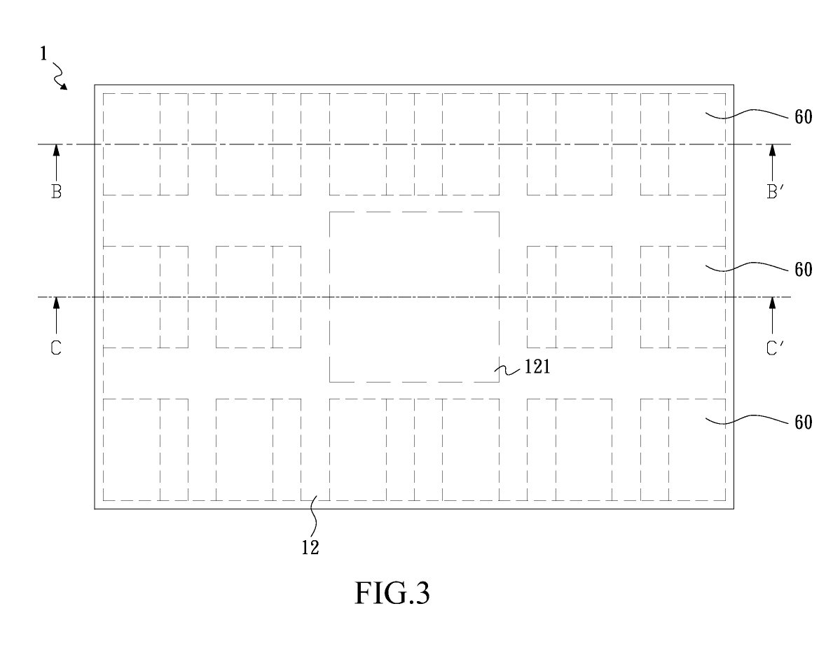

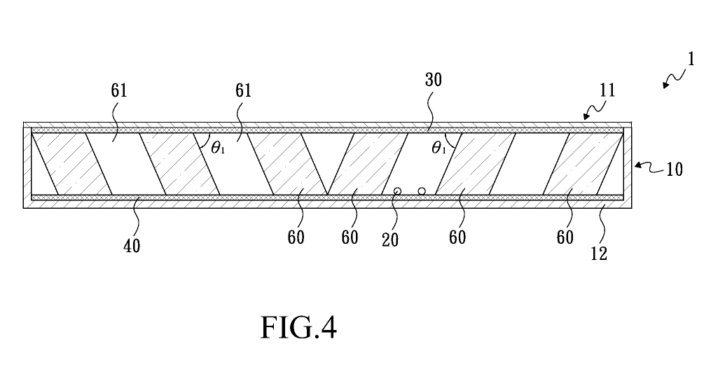

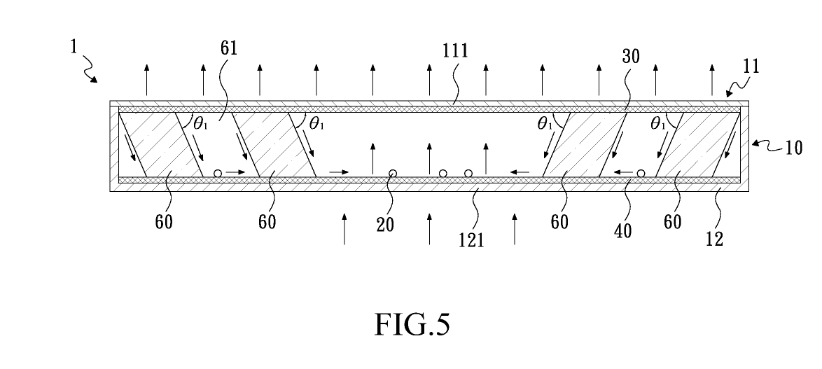

Please refer to FIG. 3, FIG. 4, and FIG. 5. According to a first embodiment of the invention, a vapor chamber 1 includes a chamber 10, a working fluid 20, an upper wick structure 30, a lower wick structure 40, and a plurality of supporting elements 60.

The chamber 10 is rectangular and includes an upper cover 11 and a bottom plate 12. A lateral edge of the bottom plate 12 is bent and is soldered to the upper cover 11 under a high temperature. Thereby, the upper cover 11 and the bottom plate 12 form an airtight space. In addition, the bottom plate 12 has a heating area 121 at a central place, and the upper cover 11 has a cooling area 111 corresponding to the heating area 121.

The working fluid 20 is contained in the vacuum chamber 10, and it has two phases. Preferably, it may be water. However, the invention is not limited thereto.

The upper wick structure 30 is located at a surface of the upper cover 11. In this embodiment, the upper wick structure 30 can be a powder sintering porous structure, a mesh porous structure, or a groove porous structure. However, the invention is not limited thereto. Further, it may be a porous structure combining the powder sintering, the mesh, and the groove. In addition, the upper wick structure 30 may also be located at surfaces of the supporting elements 60 or be located at surfaces of the upper cover 11 and the supporting elements 60 at the same time.

The lower wick structure 40 is located at a surface of the bottom plate 12. In this embodiment, the lower wick structure 40 can be a powder sintering porous structure or a mesh porous structure. However, the invention is not limited thereto. The lower wick structure 40 may be a porous structure combining the powder sintering and the mesh.

The supporting elements 60 are disposed in the vacuum chamber 10 and connect the upper cover 11 and the bottom plate 12 to support the upper cover 11. A cross-section of the supporting element 60 can be a parallelogram. However, the cross-section of the supporting element 60 may also be other polygons, as long as the same effect can be achieved. Each of the supporting elements 60 and the upper cover 11 form a first inclined angle θ₁. The first inclined angle θ₁ is an acute angle. After condensed, the working fluid 20 flows from the upper cover 11 back to the bottom plate 12 through the supporting elements 60 by the guiding of the first inclined angle θ₁. In addition, a passage 61 is formed between the two adjacent supporting elements 60. Further, if a ratio between a capillary radius of the first inclined angle θ₁ and a hydraulic radius of the passage 61 is smaller than one, the flowing resistance of the passage 61 may be too great to block the working fluid 20. Therefore, the ratio is greater than or equal to one. In addition, contacting surfaces between the supporting elements 60 and the upper cover 11 and the bottom plate 12 (according to different structures, the supporting elements 60 can directly contact the upper wick structure 30 and the lower wick structure 40) are tightly connected via molecule expansion soldering, thereby providing a better mechanical strength.

In this embodiment, preferably, the supporting elements 60 can be parallelly arranged in the chamber 10. However, the invention is not limited thereto. The supporting elements 60 may be perpendicularly or radially arranged in the chamber 10. In addition, the supporting elements 60 connect the bottom plate 12 except the heating area 121 and the upper cover 11 except the cooling area 111 (as shown in FIG. 3). That is, the heating area 121 and the cooling area 111 are not connected via the supporting elements 60. However, the invention is not limited thereto.

Please refer to FIG. 5. The vapor chamber 1 can be disposed on a heat source, to allow the heat source to contact the heating area 121 of the bottom plate 12. After the heat source runs to generate high heat, the heat can be directly transferred to the heating area 121 of the bottom plate 12, and the heat is absorbed by the working fluid 20 in the chamber 10. The working fluid 20 is converted into vapor after absorbing the heat of the heat source, thereby dissipating the high heat of the heat source. The cooling area 111 of the upper cover 11 cools the working fluid 20. After condensed, the working fluid 20 in the vapor phase leaves away from the cooling area 111 by the guiding of the upper wick structure 30. When the working fluid 20 approaches the supporting elements 60 for a certain distance, the working fluid 20 flows from the upper cover 11 to the supporting elements 60 by the guiding of the additional capillary force provided by the first inclined angle θ₁, such that the working fluid 20 can flow to the bottom plate 12 along the supporting elements 60. Afterwards, the working fluid 20 on the bottom plate 12 flows back to the heating area 121 by the guiding of the lower wick structure 40, and it recycles to dissipate the heat of the heat source.

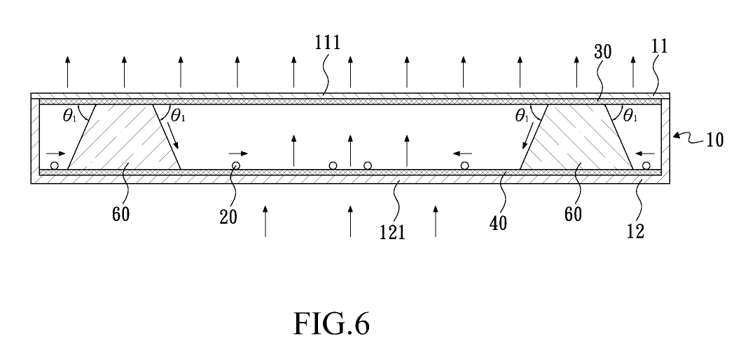

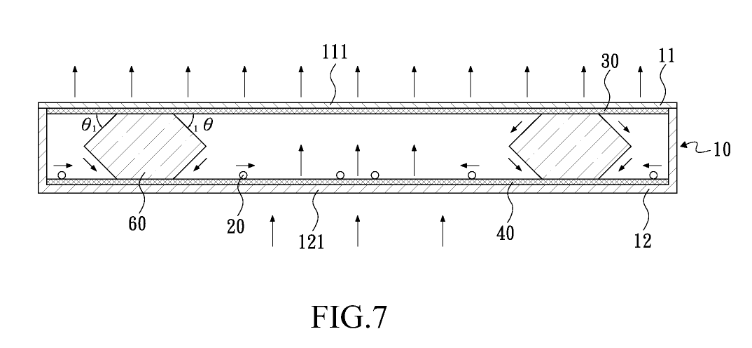

Please refer to FIG. 6 and FIG. 7. Besides the parallelogram mentioned above, a cross-section of the supporting element 60 may also be a trapezium, and the two sides and the upper cover 11 form the first inclined angle θ₁, respectively. In addition, the cross-section of the supporting element 60 may be a hexagon, and the two sides and the upper cover 11 form the first inclined angle θ₁, respectively. However, as long as the same effect can be achieved, the cross-section of the supporting element 60 may be other polygons.

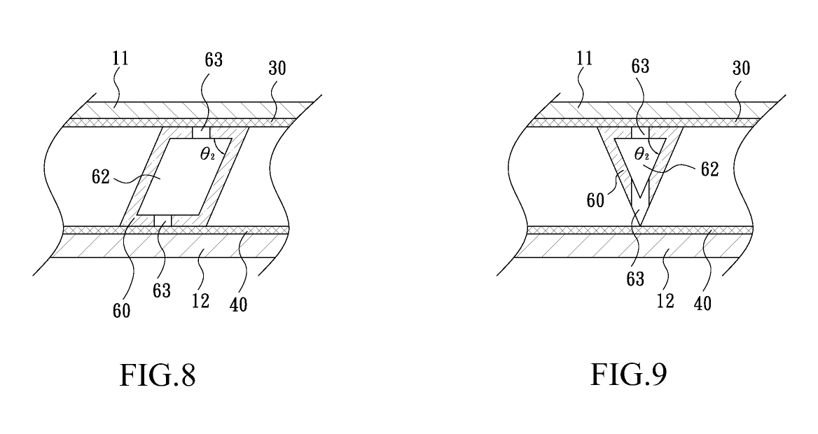

FIG. 8 is a sectional schematic diagram showing a vapor chamber according to a second embodiment of the invention. Please refer to FIG. 8. The most difference between the first embodiment and the second embodiment is that the supporting element 60 has a parallelogram through hole 62, and the through hole 62 has a second inclined angle θ₂ which is an acute angle. A ratio between a capillary radius of the second inclined angle θ₂ and a hydraulic radius of the through hole 62 is greater than or equal to one. In addition, the supporting element 60 has a plurality of connection holes 63 communicating the through hole 62 and the upper cover 11, the through hole 62 and the bottom plate 12, respectively, to allow the working fluid 20 at the upper wick structure 30 to accelerate to flow into the through hole 62 thus to allow the working fluid 20 in the through hole 62 to accelerate to flow to the bottom plate 12.

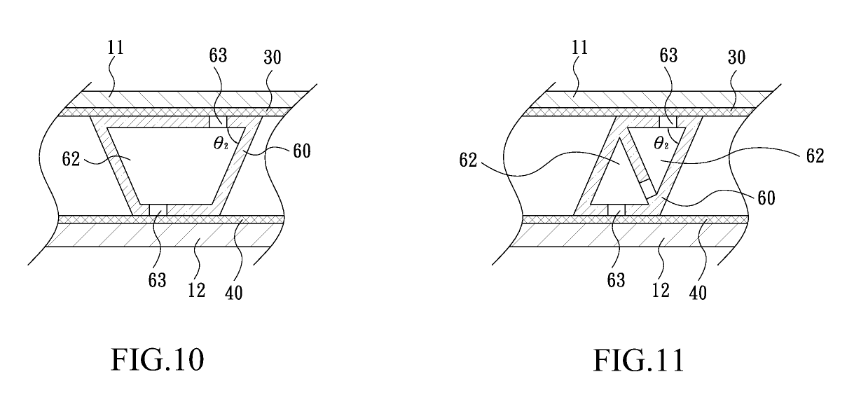

Please refer to FIG. 9 and FIG. 10. A cross-section of the supporting element 60 can be a triangle or a trapezium. A cross-section of the through hole 62 can be a triangle or a trapezium corresponding to the supporting element 60, and two sides have a second inclined angle θ₂ which is an acute angle, respectively. However, as long as the same effect can be achieved, the cross-section of the through hole 62 may be other polygons.

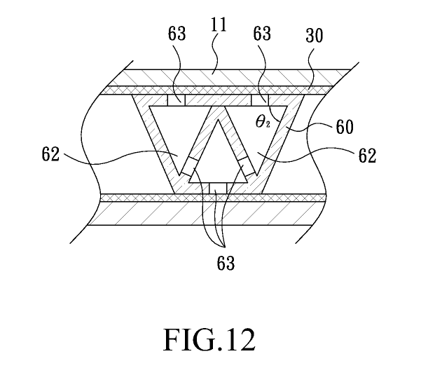

Please refer to FIG. 11 and FIG. 12. The supporting element 60 has a plurality of through holes 62, and the through holes 62 communicate with each other by connection holes 63, thus to allow the working fluid 20 in the through hole 62 adjacent to the upper cover 11 to flow to the through hole 62 adjacent to the bottom plate 12.

According to the invention, the condensed working fluid can flow back via the additional capillary force provide by the first inclined angle and the second inclined angle both of which are acute, thus to improve permeability of the wick structure, to reduce reflowing resistance of the working fluid, and to increase a mass flow rate of the working fluid, thereby improving the heat transfer capability of the vapor chamber. In addition, when the upper cover and the bottom plate are soldered under a high temperature, contacting surfaces between the supporting elements and the upper cover and the bottom plate (or the upper and lower wick structure) are tightly connected via molecule expansion soldering, thereby providing a better mechanical strength.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A vapor chamber for contacting a heat source, comprising:
a chamber including an upper cover and a bottom plate, the bottom plate used for contacting the heat source;
a working fluid contained in the chamber and converted into vapor after absorbing heat of the heat source;
a lower wick structure located at the bottom plate; and
a plurality of supporting elements connecting the upper cover and the bottom plate to support the upper cover, each of the supporting elements and the upper cover forming a first inclined angle, the working fluid in the vapor phase flowing from the upper cover back to the bottom plate through the supporting elements after condensed.

2. The vapor chamber according to claim 1, wherein the bottom plate has a heating area, and the upper cover has a cooling area corresponding to the heating area.

3. The vapor chamber according to claim 2, wherein the lower wick structure guides the working fluid on the bottom plate in flowing back to the heating area.

4. The vapor chamber according to claim 2, wherein the supporting elements connect the bottom plate except the heating area and the upper cover except the cooling area.

5. The vapor chamber according to claim 1, wherein the lower wick structure is a powder sintering structure, a mesh structure, or a combination thereof.

6. The vapor chamber according to claim 1, wherein a passage is formed between the adjacent supporting elements, and a ratio between a capillary radius of the first inclined angle and a hydraulic radius of the passage is greater than or equal to one.

7. The vapor chamber according to claim 1, wherein a cross-section of each of the supporting elements is selected from the group consisting of a parallelogram, a trapezium, a hexagon, and a polygon.

8. The vapor chamber according to claim 1, wherein each of the supporting elements comprises at least one through hole having a second inclined angle.

9. The vapor chamber according to claim 8, wherein a ratio between a capillary radius of the second inclined angle and a hydraulic radius of the through hole is greater than or equal to one.

10. The vapor chamber according to claim 8, wherein a cross-section of the through hole is selected from the group consisting of a triangle, a parallelogram, a trapezium, and a polygon.

11. The vapor chamber according to claim 8, wherein each of the supporting elements further comprises at least one connection hole for communicating the through hole and the upper cover, the through hole and the bottom plate, or the adjacent through holes.

12. The vapor chamber according to claim 1, wherein the supporting elements are arranged in the vacuum chamber parallelly, perpendicularly, or radially.

13. The vapor chamber according to claim 1, further comprising an upper wick structure located at the upper cover or the supporting elements.

14. The vapor chamber according to claim 13, wherein the upper wick structure is a powder sintering structure, a mesh structure, a groove structure, or a combination thereof.
